(19) United States
(12) Patent Application Publication
(10) Pub. No.: US 2026/0198155 A1
(43) Pub. Date: Jul. 9, 2026

(54) LIGHT-EMITTING DEVICE AND IMAGE DISPLAY DEVICE

(71) Applicant: SONY SEMICONDUCTOR SOLUTIONS CORPORATION, KANAGAWA (JP)

(72) Inventor: SOTETSU SAITO, KANAGAWA (JP)

(21) Appl. No.: 19/132,885

(22) PCT Filed: Nov. 17, 2023
(86) PCT No.: PCT/JP2023/041533

§ 371 Date: May 27, 2025

(30) Foreign Application Priority Data
Dec. 2, 2022 (JP) 2022-193717

(51) Int. Cl. H10H 29/37; H10H 29/851

(52) U.S. Cl. CPC H10H 29/37; H10H 29/851

(57) ABSTRACT

A light-emitting device according to one embodiment of the present disclosure includes: a driving substrate; a compound semiconductor layer including a light-emitting region and having and a first surface facing the driving substrate and a second surface serving as a light-emitting surface on a side opposite to the first surface; and a separating part that separates at least a portion of the compound semiconductor layer from the second surface toward the first surface for each pixel, and has an inverted tapered shape in which an angle formed between a separation surface thereof and the first surface is an obtuse angle.

### TECHNICAL FIELD

The present disclosure relates to a light-emitting device and an image display device including the same.

### BACKGROUND ART

For example, Patent Literature 1 discloses a light-emitting device that reduces crosstalk between adjacent pixels by separating the light-emitting element portions from each other for each pixel.

### CITATION LIST

### Patent Literature

Patent Literature 1: International Publication No. 2021/256113

### SUMMARY OF THE INVENTION

As described above, in the light-emitting device used in the image display device, reduction of color mixing due to light leakage between adjacent pixels is demanded.

It is desirable to provide a light-emitting device and an image display device that make it possible to reduce color mixture.

A light-emitting device according to an embodiment of the present disclosure includes a driving substrate, a compound semiconductor layer including a light-emitting region and having and a first surface facing the driving substrate and a second surface serving as a light-emitting surface on a side opposite to the first surface, and a separating part that separates at least a portion of the compound semiconductor layer from the second surface toward the first surface for each pixel, and has an inverted tapered shape in which an angle formed between a separation surface thereof and the first surface is an obtuse angle.

An image display device according to an embodiment of the present disclosure includes a light-emitting device, and includes the light-emitting device according to the embodiment of the present disclosure.

In the light-emitting device according to the embodiment of the present disclosure and the image display device according to the embodiment of the present disclosure, the separating part is provided for separating the compound semiconductor layer including the light-emitting region and having the first surface facing the driving substrate and the second surface serving as the light-emitting surface for each pixel from the second surface side toward the first surface side. The separating part has the inverted tapered shape in which an angle formed between the separation surface and the first surface is an obtuse angle. This reduces leakage of light into adjacent pixels.

### BRIEF DESCRIPTION OF THE DRAWINGS

FIG. 1 is a schematic cross-sectional diagram illustrating an example of a configuration of a light-emitting device according to an embodiment of the present disclosure.

FIG. 2 is a schematic diagram illustrating an example of a planar configuration of the entire light-emitting device illustrated in FIG. 1.

FIG. 3 is an enlarged schematic view of a part of the planar configuration of the light-emitting device illustrated in FIG. 2.

FIG. 4 is a schematic diagram illustrating a detailed configuration of the separating part illustrated in FIG. 1 and an example of an optical path of the outgoing light.

FIG. 5A is a schematic cross-sectional diagram illustrating an example of a manufacturing process of the light-emitting device illustrated in FIG. 1.

FIG. 5B is a schematic cross-sectional diagram illustrating a step following FIG. 5A.

FIG. 5C is a schematic cross-sectional diagram illustrating a step following FIG. 5B.

FIG. 5D is a schematic cross-sectional diagram illustrating a step following FIG. 5C.

FIG. 5E is a schematic cross-sectional diagram illustrating a step following FIG. 5D.

FIG. 5F is a schematic cross-sectional diagram illustrating a step following FIG. 5E.

FIG. 5G is a schematic cross-sectional diagram illustrating a step following FIG. 5F.

FIG. 5H is a schematic cross-sectional diagram illustrating a step following FIG. 5G.

FIG. 5I is a schematic cross-sectional diagram illustrating a step following FIG. 5H.

FIG. 5J is a schematic cross-sectional diagram illustrating a step following FIG. 5I.

FIG. 5K is a schematic cross-sectional diagram illustrating a step following FIG. 5J.

FIG. 5L is a schematic cross-sectional diagram illustrating a step following FIG. 5K.

FIG. 6A is a schematic cross-sectional diagram illustrating a step following FIG. 7K.

FIG. 6B is a schematic cross-sectional diagram illustrating a step following FIG. 6A.

FIG. 6C is a schematic cross-sectional diagram illustrating a step following FIG. 6B.

FIG. 6D is a schematic cross-sectional diagram illustrating a step following FIG. 6C.

FIG. 6E is a schematic cross-sectional diagram illustrating a step following FIG. 6D.

FIG. 6F is a schematic cross-sectional diagram illustrating a step following FIG. 6E.

FIG. 6G is a schematic cross-sectional diagram illustrating a step following FIG. 6F.

FIG. 6H is a schematic cross-sectional diagram illustrating a step following FIG. 6G.

FIG. 6I is a schematic cross-sectional diagram illustrating a step following FIG. 6H.

FIG. 6J is a schematic cross-sectional diagram illustrating a step following FIG. 6I.

FIG. 6K is a schematic cross-sectional diagram illustrating a step following FIG. 6J.

FIG. 6L is a schematic cross-sectional diagram illustrating a step following FIG. 7K.

FIG. 6M is a schematic cross-sectional diagram illustrating a step following FIG. 6L.

FIG. 6N is a schematic cross-sectional diagram illustrating a step following FIG. 6M.

FIG. 6O is a schematic cross-sectional diagram illustrating a step following FIG. 6N.

FIG. 6P is a schematic cross-sectional diagram illustrating a step following FIG. 6O.

FIG. 6Q is a schematic cross-sectional diagram illustrating a step following FIG. 6P.

FIG. 6R is a schematic cross-sectional diagram illustrating a step following FIG. 6Q.

FIG. 6S is a schematic cross-sectional diagram illustrating a step following FIG. 6R.

FIG. 6T is a schematic cross-sectional diagram illustrating a step following FIG. 6S.

FIG. 6U is a schematic cross-sectional diagram illustrating a step following FIG. 6T.

FIG. 6V is a schematic cross-sectional diagram illustrating a step following FIG. 6U.

FIG. 6W is a schematic cross-sectional diagram illustrating a step following FIG. 6V.

FIG. 7 is a schematic cross-sectional diagram illustrating an example of a configuration of a light-emitting device according to Modification 1 of the present disclosure.

FIG. 8A is a schematic cross-sectional diagram illustrating an example of a manufacturing process of a light-emitting device illustrated in FIG. 7.

FIG. 8B is a schematic cross-sectional diagram illustrating a step following FIG. 8A.

FIG. 8C is a schematic cross-sectional diagram illustrating a step following FIG. 8B.

FIG. 8D is a schematic cross-sectional diagram illustrating a step following FIG. 8C.

FIG. 8E is a schematic cross-sectional diagram illustrating a step following FIG. 8D.

FIG. 9 is an enlarged schematic view of a part of a planar configuration of a light-emitting device according to Modification 2 of the present disclosure.

FIG. 10 is a perspective diagram illustrating an example of a configuration of an image display device according to an application example of the present disclosure.

FIG. 11 is a schematic diagram illustrating an example of a wiring layout of the image display device illustrated in FIG. 10.

FIG. 12 is a perspective diagram illustrating an example of a configuration of an image display device according to an application example of the present disclosure.

FIG. 13 is a perspective diagram illustrating a configuration of the mounting substrate illustrated in FIG. 12.

FIG. 14 is a perspective diagram illustrating a configuration of the unit substrate illustrated in FIG. 13.

FIG. 15 is a diagram illustrating an example of an image display device according to an application example of the present disclosure.

### MODES FOR CARRYING OUT THE INVENTION

Hereinafter, an embodiment of the present disclosure will be described in detail with reference to the drawings. The following description is a specific example of the present disclosure, but the present disclosure is not limited to the following embodiment. In addition, the present disclosure is not limited to arrangement, dimensions, dimensional ratios, and the like of the constituent elements illustrated in the drawings. It is to be noted that the description is given in the following order.
1. Embodiment (an example of light-emitting device that separate between light-emitting elements using a separating part having an inverted tapered shape)
1-1. Configuration of display device
1-2. Method of manufacturing light-emitting device
1-3. Workings and Effects
2. Modifications
3-1. Modification 1 (another example of the light-emitting device)
3-2. Modification 2 (another example of the light-emitting device)
3. Application Examples

### 1. Embodiment

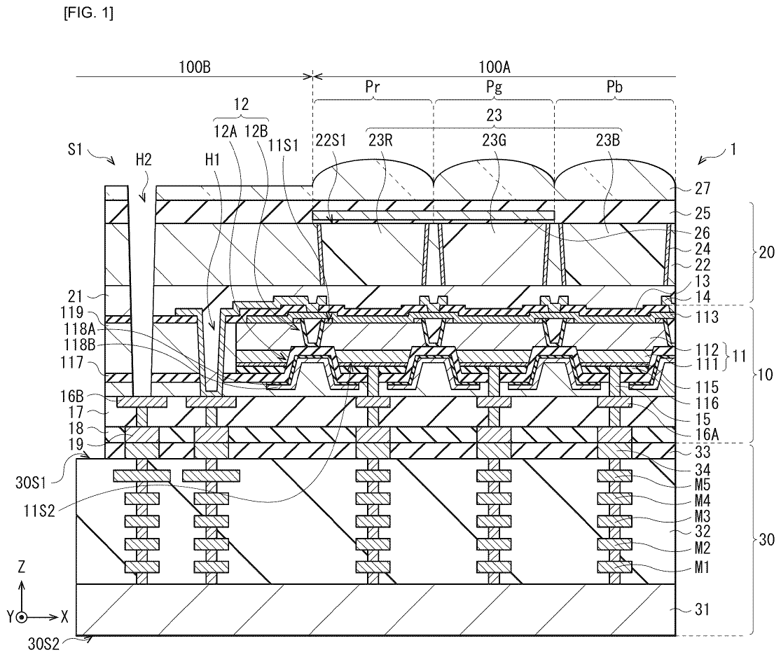

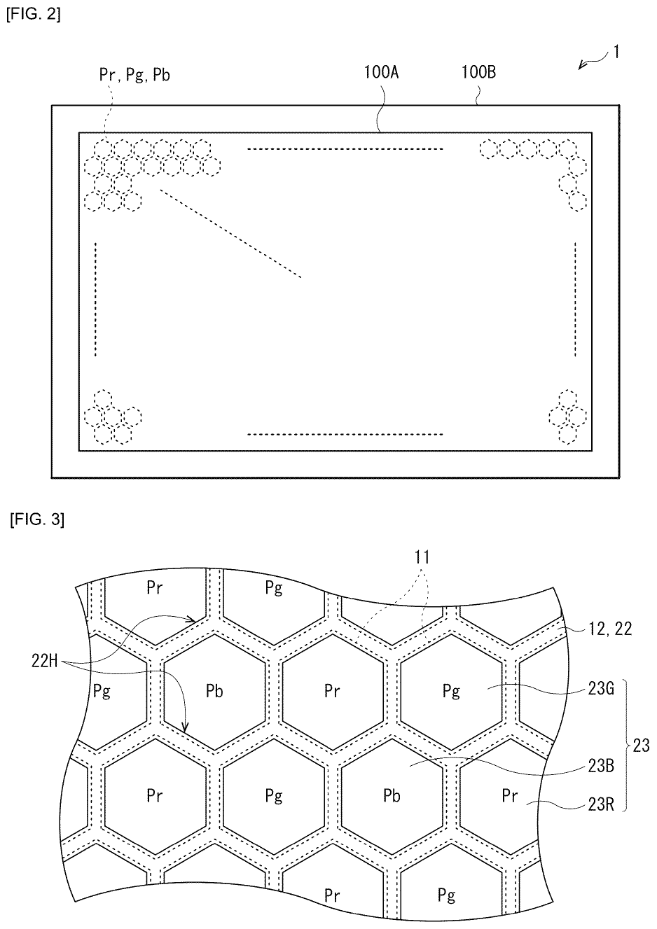

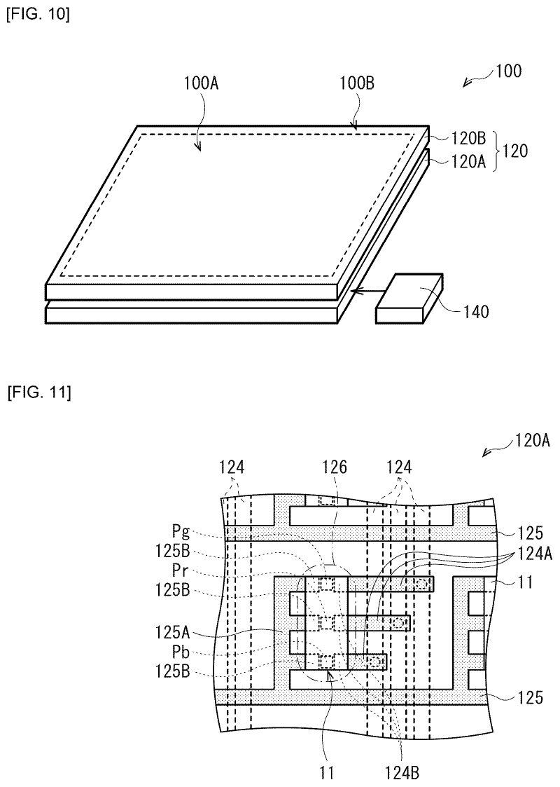

FIG. 1 schematically illustrates an example of a cross-sectional configuration of a light-emitting device (light-emitting device 1) according to an embodiment of the present disclosure. FIG. 2 schematically illustrates an example of the overall planar configuration of the light-emitting device 1 illustrated in FIG. 1. The light-emitting device 1 is suitably applicable to an image display device called a so-called LED display (for example, the image display device 100, see FIG. 10).

### (1-1. Configuration of Light-Emitting Device)

The light-emitting device 1 includes a display portion 100A in which a plurality of pixels (for example, a red pixel Pr, a green pixel Pg, and a blue pixel Pb) are arranged in a two-dimensional array, and a frame portion 100B provided around the display portion. In the light-emitting device 1, for example, a light-emitting part 10 in which light-emitting elements 11 are disposed on a plurality of pixels (for example, a red pixel Pr, a green pixel Pg, and a blue pixel Pb) in the display portion 100A and a wavelength conversion part 20 are stacked in this order on a surface 30S1 of a driving substrate 30 having opposed surfaces (surface 30S1) and a back surface (surface 30S2).

The light-emitting device 1 includes a separating part 12 that separates the compound semiconductor layers 110 having the surface 11S1 serving as the light-emitting surface and the surface 11S2 facing the driving substrate 30 facing away from the surface 11S1 for each pixel (for example, the red pixel Pr, the green pixel Pg, and the blue pixel Pb). In the present embodiment, the separating part 12 includes a first separating part 12A that separates the compound semiconductor layer 110 from the surface 11S1 side toward the surface 11S1 side to the middle, and a second separating part 12B that separates the compound semiconductor layer 110 from the surface 11S2 side toward the surface 11S2 side and whose bottom portion is in contact with the bottom portion of the first separating part 12A. The second separating part 12B has an inverted tapered shape in which an angle formed between the separation surface 12BS and the surface 11S2 of the compound semiconductor layer 110 is an obtuse angle.

As described above, the light-emitting part 10 includes a plurality of pixels (for example, a red pixel Pr, a green pixel Pg, and a blue pixel Pb) arranged in a two-dimensional array in the display portion 100A. Specifically, the plurality of pixels (for example, the red pixel Pr, the green pixel Pg, and the blue pixel Pb) have, for example, a substantially regular hexagonal planar shape as illustrated in FIG. 3, and are arranged in, for example, a honeycomb shape. Each of the plurality of pixels (for example, the red pixel Pr, the green pixel Pg, and the blue pixel Pb) includes a light-emitting element 11 in which the compound semiconductor layers 110 are separated by the separating part 12. In other words, a plurality of light-emitting elements 11 having substantially regular hexagonal planar shapes, for example, are arranged in two-dimensional arrays on the display portion 100A. An electrode layer 113, an insulating layer 13, and an extraction electrode 14 are formed in this order on the surface 11S1 sides of the plurality of light-emitting elements 11. On the surface 11S2 sides of the plurality of light-emitting elements 11, an electrode layer 115 and an insulating layer 116 provided for each of the light-emitting elements 11, a protective layer 117, an insulating film 118B, and a reflective film 118A which are consecutive to the plurality of light-emitting elements 11, and a buried layer 119 in which the plurality of light-emitting elements 11 are embedded are formed. The plurality of light-emitting elements 11 are further formed in this order on the surface 11S2 sides with a plug 15 provided for each element, an insulating layer 17 including a pad portion 16A and a pad electrode 16B, and an insulating layer 18 including a pad portion 19 for electrically and physically bonding the light-emitting part 10 and the driving substrate 30.

The light-emitting element 11 corresponds to a specific example of the “light-emitting part” in the embodiment of the present disclosure. The light-emitting element 11 is a solid-state light-emitting element that emits light of a predetermined wavelength band from the surface 11S1, and is, for example, a LED (Light Emitting Diode) chip. The term “LED chip” refers to a wafer cut out from a wafer used for growing crystals, and is not a package-type wafer covered with a molded plastic or the like. LED chip is, for example, 5 μm or more and 100 μm or less, and is called a so-called micro LED.

In the light-emitting element 11, the first conductivity type layer 111 and the second conductivity type layer 112 are stacked in this order. In the light-emitting element 11, a light-emitting region is formed at the interface and the vicinity of the first conductivity type layer 111 and the second conductivity type layer 112, and light in a blue band of, for example, 430 nm or more and 500 nm or less is extracted from the light-emitting region. In addition, for example, light having a wavelength corresponding to the ultraviolet region (ultraviolet light) may be extracted from the light emitting region.

The first conductivity type layer 111 includes, for example, a p-type GaN based semiconducting material. The second conductivity type layer 112 includes, for example, n-type GaN based semiconducting material. In the light-emitting element 11, the upper surface of the second conductivity type layer 112 is a light-emitting surface (surface 11S1), and the surface 11S1 corresponds to a specific example of the “second surface” in the embodiment. The lower surface (surface 11S2) of the first conductivity type layer 111, which is opposed to the surface 11S1, corresponds to a specific example of the “first surface” in the embodiment.

As described above, the separating part 12 separates the compound semiconductor layers 110 to form the light emitting elements 11 for each pixel (for example, the red pixel Pr, the green pixel Pg, and the blue pixel Pb). The separating part 12 includes a first separating part 11S2 that separates the compound semiconductor layer 110 from the surface 11S1 toward the surface 11S2, and a second separating part 12B that separates the compound semiconductor layer 110 from the surface 11S1 toward the surface 11S2. The first separating part 12A and the second separating part 12B are in contact with each other at their bottom portions, and thereby penetrate through the compound semiconductor layers 110. The separating part 12 corresponds to a specific example of a “separating part” in an embodiment of the present disclosure. The first separating part 12A corresponds to a specific example of the “first separating part” in the embodiment of the present disclosure, and the second separating part 12B corresponds to a specific example of the “second separating part” in the embodiment of the present disclosure.

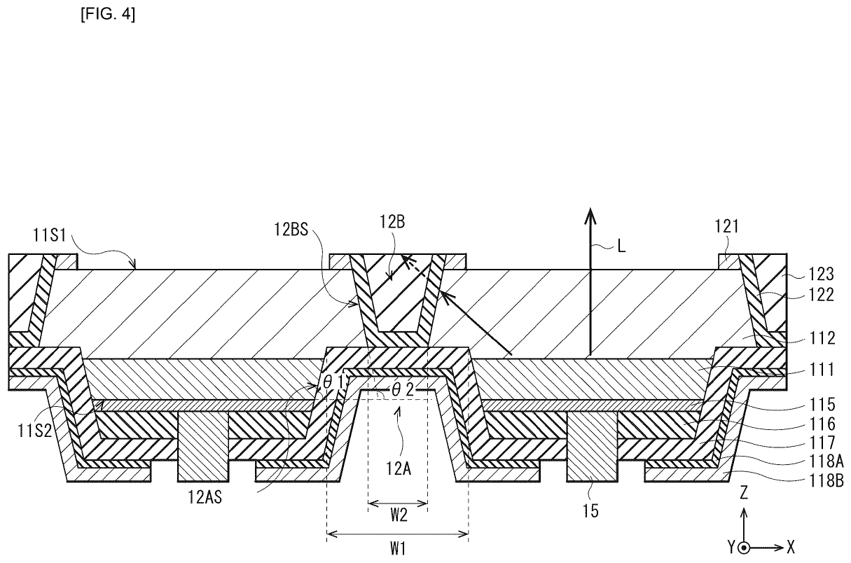

FIG. 4 schematically illustrates a detailed configuration of the separating part 12 and an example of an optical path of the outgoing light L.

The first separating part 12A has a forward tapered shape in which an angle (θ1) formed between the separation surface 12AS for separating the compound semiconductor layer 110 and the surface 11S2 of the compound semiconductor layer 110 is an acute angle.

The second separating part 12B has an inversely tapered shape in which an angle (θ2) formed between the separation surface 12BS for separating the compound semiconductor layer 110 and the surface 11S2 of the compound semiconductor layer 110 is obtuse. As a result, color mixing caused by incidence on the wavelength conversion layer 23 (for example, the red wavelength conversion layer 23R, the green wavelength conversion layer 23G, and the blue wavelength conversion layer 23B) provided in the adjacent-arranged pixels (for example, the red pixel Pr, the green pixel Pg, and the blue pixel Pb) of the light (the emitted light L) emitted from the light emitting area in the oblique direction, for example, is reduced. It should be noted that the effect of reducing color mixing due to the inverted tapered shape of the second separating part 12B is in a trade-off relation with the light-extraction efficiency. Therefore, the angle (θ2) formed between the separation surface 12BS and the surface 11S2 of the compound semiconductor layer 110 is preferably greater than 90°, for example, 100° or less. Accordingly, it is possible to maintain sufficient light extraction efficiency while reducing color mixture.

The first separating part 12A is a groove that separates the compound semiconductor layers 110 from the surface 11S2 side toward the surface 11S1 side. In the groove, protective layers 117 are provided as side walls over the separation surface 12AS and the bottom surface. In the groove, the reflective film 118A and the insulating film 118B are further provided on the protective layer 117 in this order, similarly to the protective layer 117. The groove is further filled with a buried layer 119.

The second separating part 12B is a groove that separates the compound semiconductor layers 110 from the surface 11S1 side toward the surface 1S2 side. A reflective film 122 is provided in the groove across the separation surface 12BS and the bottom surface. Thus, for example, the light (emitted light L) emitted from the light emitting region in an oblique direction is reflected by the reflective film 122, and incidence on the wavelength conversion layer 23 (for example, the red wavelength conversion layer 23R, the green wavelength conversion layer 23G, and the blue wavelength conversion layer 23B) provided in the adjacent pixels (for example, the red pixel Pr, the green pixel Pg, and the blue pixel Pb) is suppressed. The groove is further filled with an insulating film 123.

The reflective film 122 is formed using, for example, a metal material having light reflectivity. Examples of the metal material for forming the reflective film 122 include a metal having a high reflectance in the visible light region. Specific examples include silver (Ag), aluminum (Al), copper (Cu), gold (Au), platinum (Pt), rhodium (Rh), and alloys thereof. The insulating film 123 includes, for example, an insulating material such as silicon oxide (SiO) or silicon nitride (SiN). The material filled in the groove may be filled with a resin material in addition to the insulating material. Accordingly, it is possible to reduce the effect of the thermal expansion coefficient difference between the compound semiconductor layers 110 and the support substrate 31 made of, for example, Si.

The width (W1) of the bottom portion of the first separating part 12A is, for example, larger than the width (W2) of the bottom portion of the second separating part 12B (W1>W2). This ensures margins for registration when forming the second separating part 12B in the step after forming the first separating part 12A, which will be described later. Note that the relation between the width (W1) of the bottom portion of the first separating part 12A and the width (W2) of the bottom portion of the second separating part 12B is not limited to this. For example, the width (W1) of the bottom portion of the first separating part 12A and the width (W2) of the bottom portion of the second separating part 12B may be the same (W1=W2), or the width (W1) of the bottom portion of the first separating part 12A may be smaller than the width (W2) of the bottom portion of the second separating part 12B.

The electrode layer 113 is formed continuously on the surface 11S1 of each of the plurality of light-emitting elements 11 as a common electrode for the plurality of light-emitting elements 11. The electrode layer 113 is in ohmic contact with the second conductivity type layer 112, and includes a transparent electrode material such as ITO, indium-zinc-oxide (IZO), tin-oxide (SnO), or TiO.

The insulating layer 13 buries irregulars formed above the plurality of light-emitting elements 11. The insulating layers 13 are formed of, for example, silicon oxide (SiO), silicon nitride (SiN), or the like.

The extraction electrode 14 applies a voltage to the second conductivity type layer 112 of each of the plurality of light-emitting elements 11, and is electrically coupled to the electrode layer 113 via an opening provided in the insulating layer 13 between adjacent light-emitting elements 11, for example. In the display portion 100A, the extraction electrode 14 is formed continuously between adjacent light-emitting elements 11 so as to avoid the surface 11S1 of the plurality of light-emitting elements 11 arranged in a honeycomb shape, for example, and extends to a part of the frame portion 100B. The extraction electrode 14 formed on the frame portion 100B is electrically coupled to the pad electrode 16B via an opening H1 penetrating through the insulating layer 13, the buried layer 119, and the protective layer 117. The extraction electrode 14 is formed using, for example, a multi-layer film (Ti/Al) of titanium (Ti) and aluminum (Al), or a multi-layer film (Cr/Au) of chromium (Cr) and gold (Au).

An electrode layer 115 is formed on the lower surface (surface 11S2) of the first conductivity type layer 111 of the light-emitting element 11. The electrode layer 115 is in ohmic contact with the first conductivity type layer 111, and is formed using a transparent conductive material such as a multi-layer film (Ni/Au) of nickel (Ni) and gold (Au), or ITO.

The insulating layer 116 is provided on the electrode layer 115. The insulating layers 116 includes, for example, silicon oxide (SiO), silicon nitride (SiN), or the like.

The light emitting element 11 has a mesa shape including a portion of the first conductivity type layer 111 and the second conductivity type layer 112 on the driving substrate 30 side. The surface 11S2 of the mesa-shaped light-emitting element 11 and the side surfaces of the first conductivity type layer 111 and a part of the second conductivity type layer 112 are covered with the protective layer 117. The protective layer 117 includes, for example, silicon oxide (SiO), silicon nitride (SiN), or the like.

Further, a laminated film made of a reflective film 118A and an insulating film 118B is provided on the protective layer 117. The stacked film is continuously formed in the plurality of light-emitting elements 11. The laminated film has an opening 118H on the surface 11S2 of the light-emitting element 11, and a plug 15 is formed in the opening 118H. The reflective film 118A is formed using, for example, a light-reflective metallic material. Examples of the metal material for forming the reflective film 118A include metals having a high-reflectance in the visible-light range. Specific examples include silver (Ag), aluminum (Al), copper (Cu), gold (Au), platinum (Pt), rhodium (Rh), and alloys thereof. The insulating film 118B includes, for example, silicon oxide (SiO), silicon nitride (SiN), or the like.

The buried layer 119 buries the plurality of light-emitting elements 11 and forms a flat surface and a back surface of the light-emitting part 10. The buried layers 119 are formed of, for example, silicon oxide (SiO), silicon nitride (SiN), or the like.

The plug 15 applies a voltage to the first conductivity type layer 111 of each of the plurality of light emitting elements 11. The plug 15 includes, for example, copper (Cu), aluminum (Al), tungsten (W), silver (Ag), or an alloy thereof.

An insulating layer 17 is provided on the driving substrate 30 side of the buried layer 119. In the insulating layers 17, a plurality of pad portions 16A and a plurality of pad electrodes 16B and vias provided in the frame portions 100B are formed in the respective light-emitting elements 11A in the display portion 100A. The insulating layers 17 are formed of, for example, silicon oxide (SiO), silicon nitride (SiN), or the like. The pad portion 16A, the pad electrode 16B, and the via are formed using, for example, copper (Cu), aluminum (Al), tungsten (W), silver (Ag), or an alloy thereof.

Further, on the driving substrate 30 side of the insulating layer 17, an insulating layer 18 forming a bonding surface with the driving substrate 30 and a pad portion 19 formed to be embedded in the insulating layer 18 are provided. The insulating layers 18 are formed of, for example, silicon oxide (SiO), silicon nitride (SiN), or the like. The pad portion 19 includes, for example, Cu.

The wavelength conversion part 20 is provided on the light-extraction surface S1 of the light-emitting part 10. The wavelength conversion part 20 includes a planarization layer 21, a partition wall layer 22 having an opening 22H for each of the light-emitting elements 11, for example, and a wavelength conversion layer 23 formed in the opening 22H. A reflective film 24 is further provided between the partition wall layer 22 and the wavelength conversion layer 23. A protective layer 25 is further provided on the light emitting surface S1 of the wavelength conversion layer 23, and a wavelength selection layer 26 is provided in the protective layer 25. On the protective layer 25, an on-chip lens layer 27 is further provided.

The planarization layer 21 is for planarizing the surface of the light-emitting part 10 on the light extraction surface S1. The planarization layer 21 includes, for example, silicon oxide (SiO), silicon nitride (SiN), or the like.

When the light-emitting device 1 is applied to the image display device 100, the partition wall layer 22 suppresses color mixing due to light leakage between adjacent RGB pixels (the red pixel Pr, the green pixel Pg, and the blue pixel Pb). The partition wall layer 22 has, for example, a honeycomb structure. Specifically, as illustrated in FIG. 3, the partition wall layers 22 each have, for example, a substantially regular hexagonal opening 22H for each of the plurality of light-emitting elements 11 arranged in an array. The opening 22H has, for example, an inclined surface of less than 90° with respect to the surface 20S2 of the wavelength conversion part 20 facing away from the surface 20S1 in the cross-sectional view. That is, the partition wall layers 22 have a tapered shape between adjacent color pixels Pr, Pg, and Pb in a cross-sectional view. The partition wall layers 22 are preferably formed using a material having high thermal conductivity and high electric conductivity, and are formed using a metallic material such as copper (Cu), aluminum (Al), gold (Au), nickel (Ni), and platinum (Pt).

The wavelength conversion layer 23 corresponds to a specific example of a “wavelength conversion layer” in an embodiment of the present disclosure. The wavelength conversion layers 23 are for converting light emitted from the plurality of light-emitting elements 11 into a desired wavelength (for example, red (R)/green (G)/blue (B)) and emitting the light, and are formed in an opening 22H provided above the light-emitting elements 11. Specifically, the red pixel Pr is provided with a red wavelength conversion layer 23R for converting light emitted from the light emitting element 11 into red band light (red light), a green wavelength conversion layer 23G for converting light emitted from the light emitting element 11 into green band light (green light) in the green pixel Pg, and a blue wavelength conversion layer 23B for converting light emitted from the light emitting element 11 into blue band light (blue light) in the blue pixel Pb.

Each wavelength conversion layer 23R, 23G, and 23B may be formed using quantum dots corresponding to each color. In particular, if red light is to be obtained, the quantum dots may be selected from, for example, InP, GaInP, InAsP, CdSe, CdZnSe, CdTeSe or CdTe. When green light is to be obtained, the quantum dots may be selected from, for example, InP, GaInP, ZnSeTe, ZnTe, CdSe, CdZnSe, CdS or CdSeS. When blue light is to be obtained, it may be selected from ZnSe, ZnTe, ZnSeTe, CdSe, CdZnSe, CdS, CdZnS and CdSeS, etc. When blue light is emitted from the light-emitting element 11 as described above, the blue wavelength conversion layer 23B may be formed of a resin layer having light transmittance.

The reflective film 24 is provided on the side surface of the opening 22H for efficiently extracting the respective color lights emitted from the light-emitting element 11 and converted in the respective wavelength conversion layers 23R, 23G, and 23B from the light extraction surface (surface 22S1) of the wavelength conversion layer 23. The reflective film 24 is formed using a metal material having light reflectivity. Examples of the metal material for forming the reflective film 24 include a metal having a high reflectance in the visible light region. Specific examples include silver (Ag), aluminum (Al), copper (Cu), gold (Au), platinum (Pt), rhodium (Rh), and alloys thereof.

Note that the reflective film 24 is not necessarily formed when the partition wall layer 22 is formed using the above-described light-reflective metal material.

The protective layer 25 includes, for example, silicon oxide (SiO), silicon nitride (SiN), or the like to protect the front face of the light-emitting device 1.

A wavelength selection layer 26 is provided in the protective layer 25 over the red pixel Pr and the green pixel Pg. The wavelength selection layer 26 selectively reflects, for example, light in the blue band (blue light), thereby improving the color purity of the red light and the green light extracted from the red pixel Pr and the green pixel Pg, respectively.

The on-chip lens layer 27 is provided so as to cover the entire surfaces of the display portion 100A and the frame portion 100B. The on-chip lens layer 27 includes a light-transmissive material, and includes, for example, a single-layer film made of any one of silicon oxide (SiO), silicon nitride (SiN), silicon oxynitride (SiCN), and the like, or a stacked film made of two or more of them.

The frame portion 100B is provided with an opening H2 that penetrates through the on-chip lens layer 27, the protective layer 25, the partition wall layer 22, the planarization layer 21, the insulating layer 13, the buried layer 119, and the protective layer 117 and reaches the pad electrode 18B. The pad electrode 18B exposed at the bottom of the opening H2 is used as an external connecting electrode.

The driving substrate 30 is provided with a driving circuit or the like for controlling driving of the plurality of light-emitting elements 11 arranged on the display portion 100A. The driving substrate 30 includes, for example, a support substrate 31 made of Si, an interlayer insulating layer 32 provided on the support substrate 31 and including a plurality of wiring layers (for example, wiring layers M1, M2, M3, M4, and M5) and vias electrically connecting the wiring layers, and a pad portion 34 embedded in the insulating layer 33 and the insulating layer 33 forming a bonding surface with the light-emitting part 10.

The interlayer insulating layer 32 includes, for example, silicon oxide (SiO), silicon nitride (SiN), or the like.

The wiring layers M1, M2, M3, M4, and M5 and the vias electrically connecting the wiring layers are formed using, for example, copper (Cu), aluminum (Al), tungsten (W), silver (Ag), or alloys thereof. The insulating layer 33 includes, for example, silicon oxide (SiO), silicon nitride (SiN), or the like. The pad portion 35 includes, for example, Cu.

### (1-2. Manufacturing Method of Light-Emitting Device)

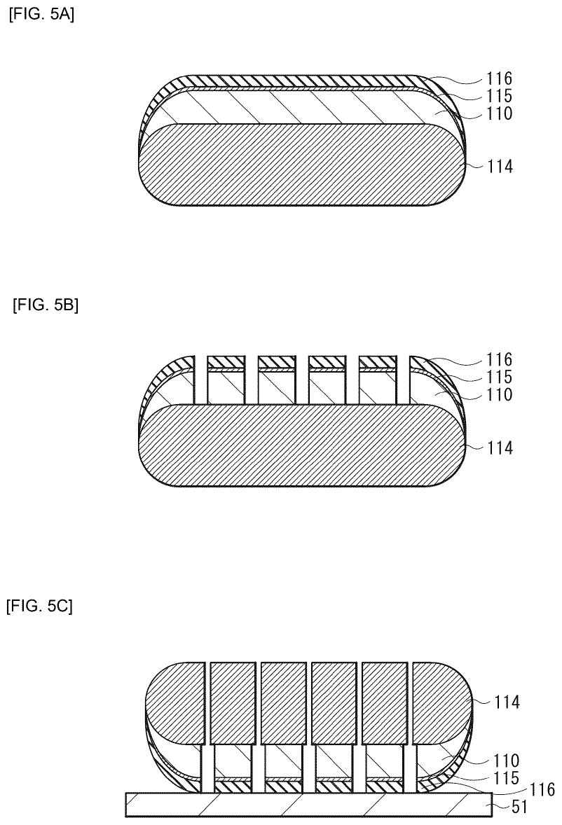

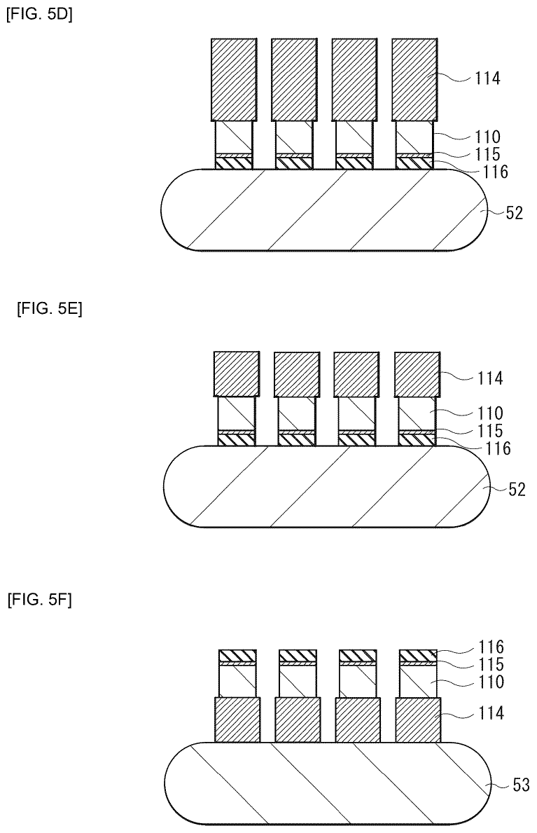

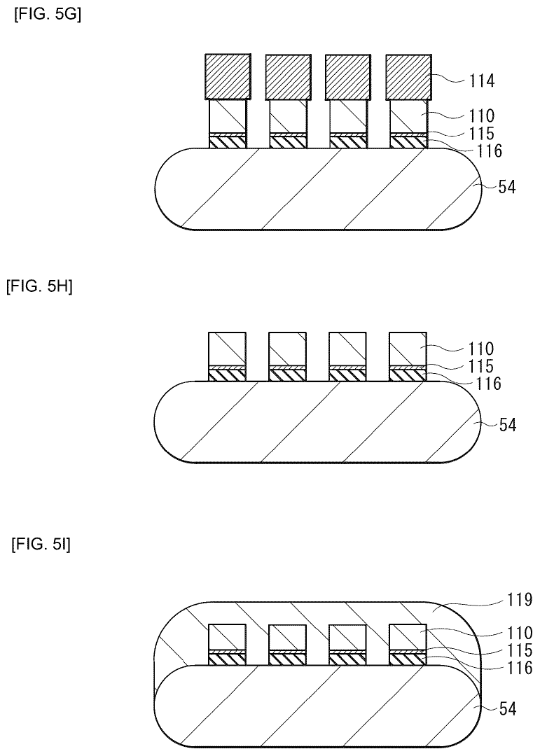

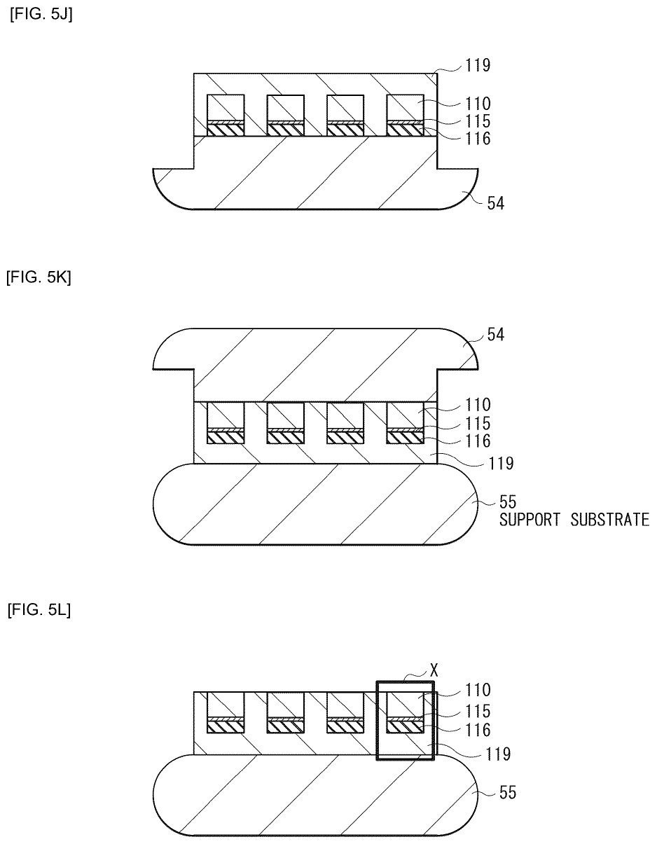

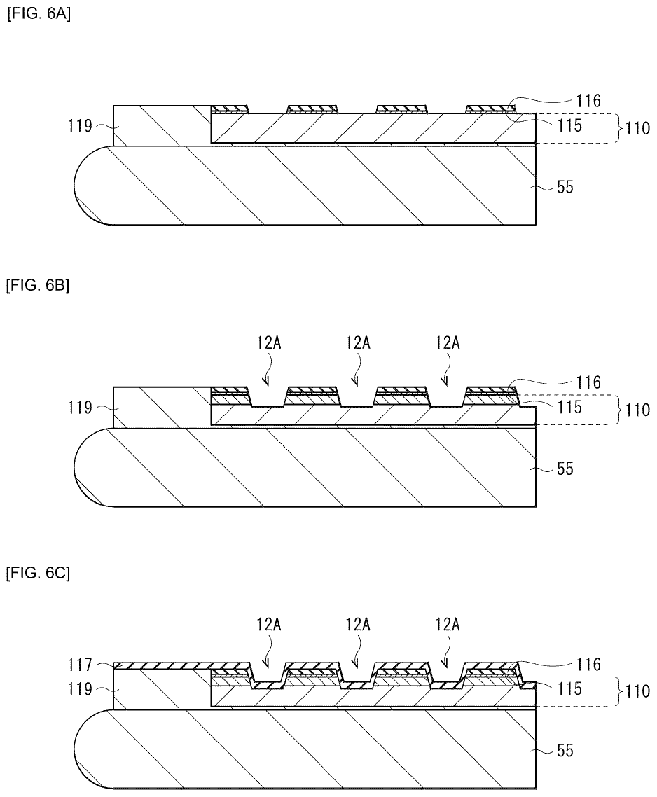

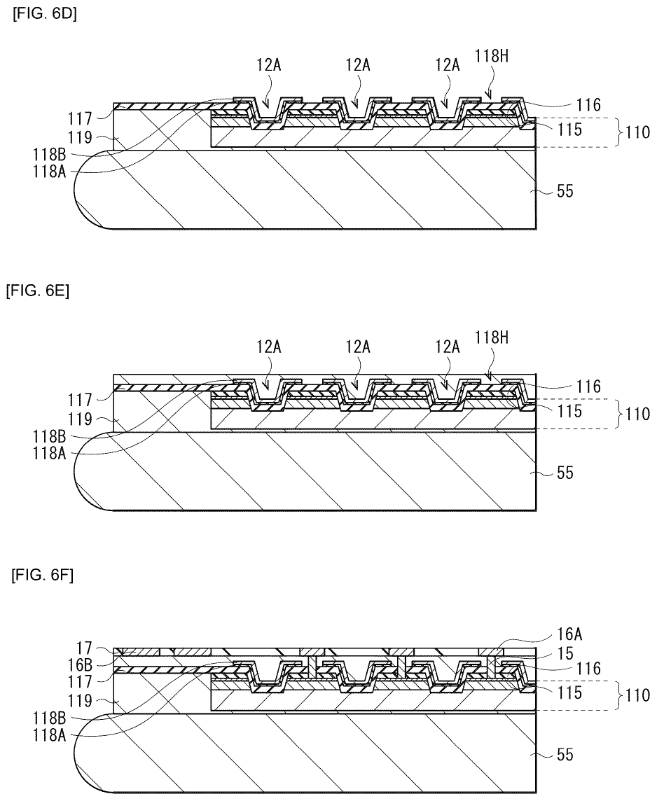

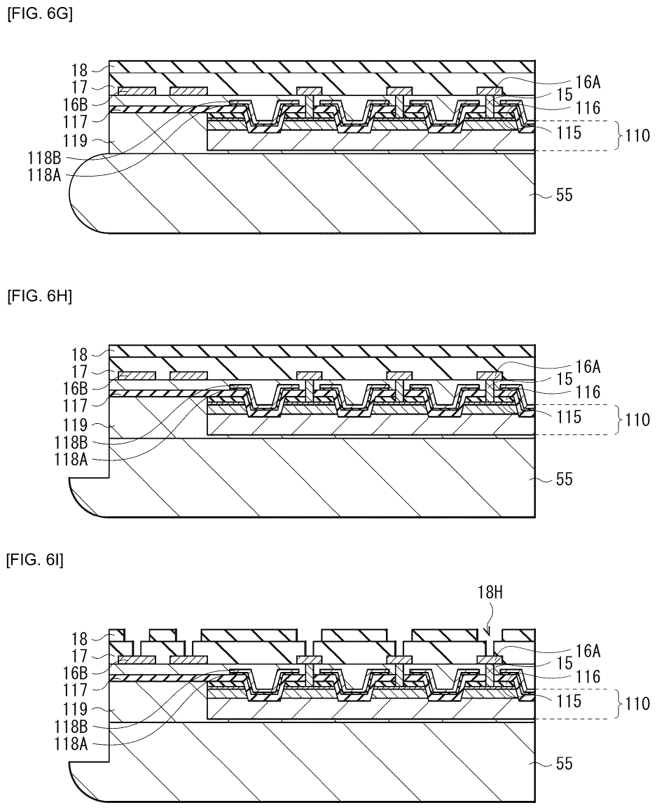

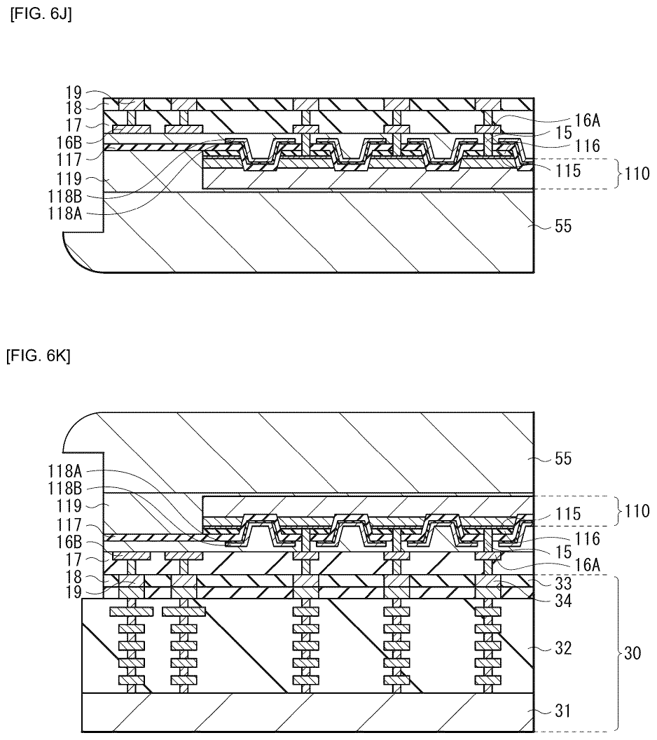

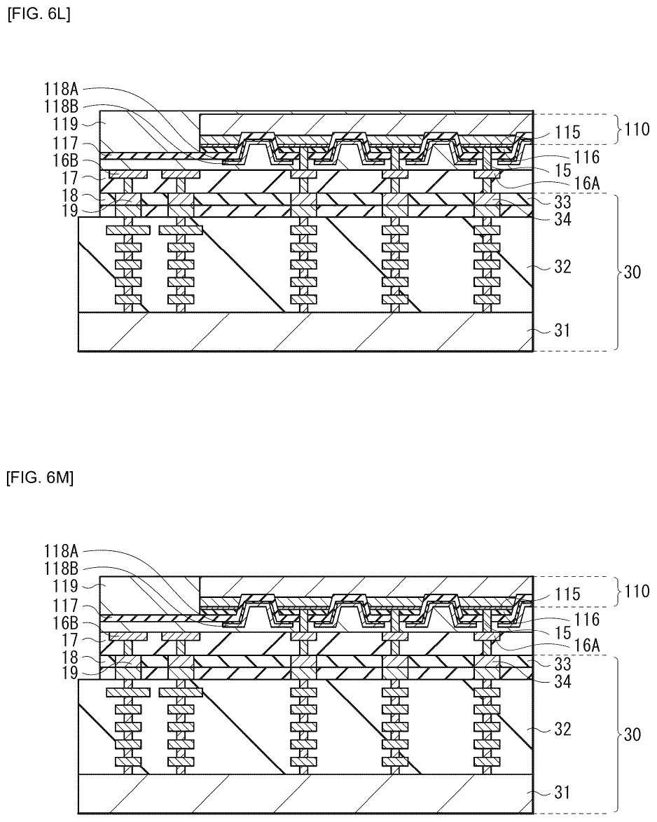

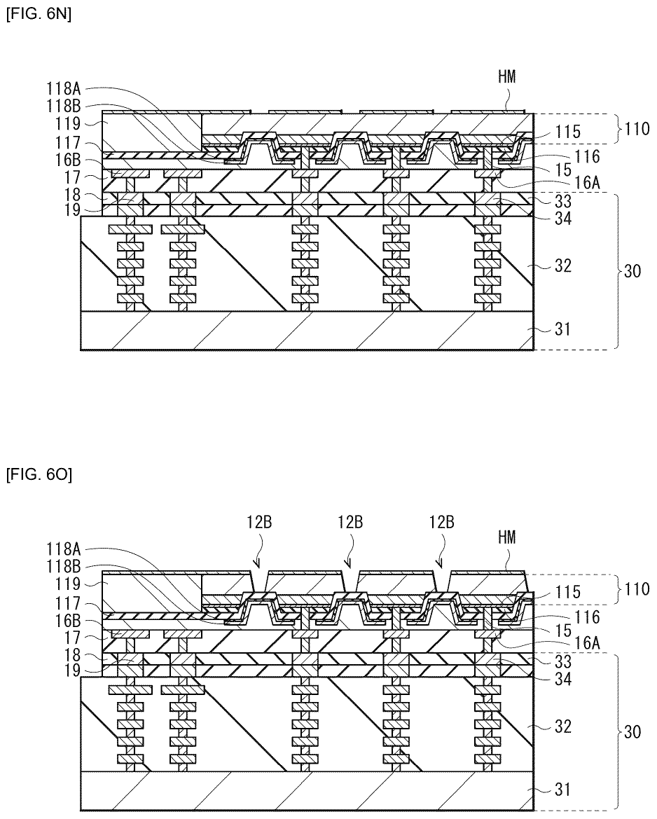

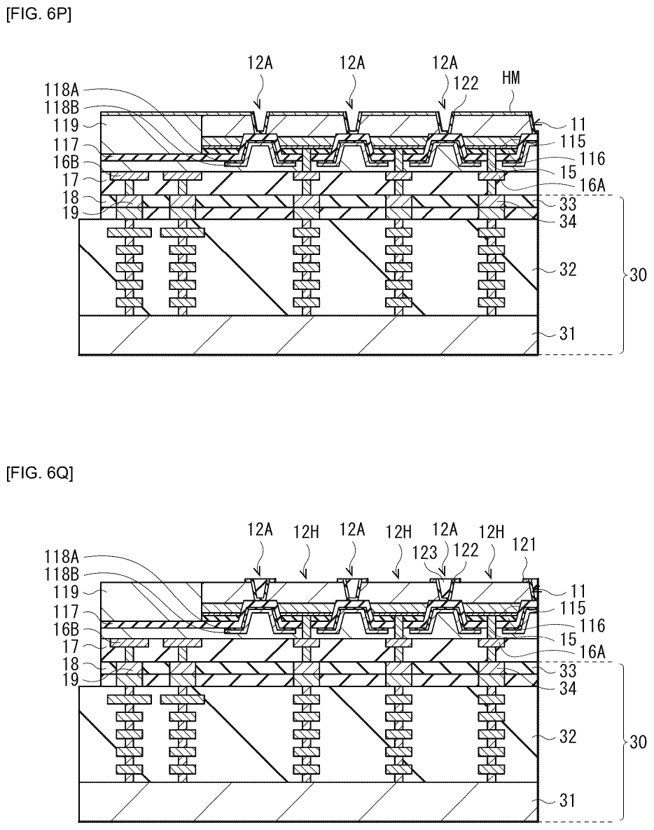

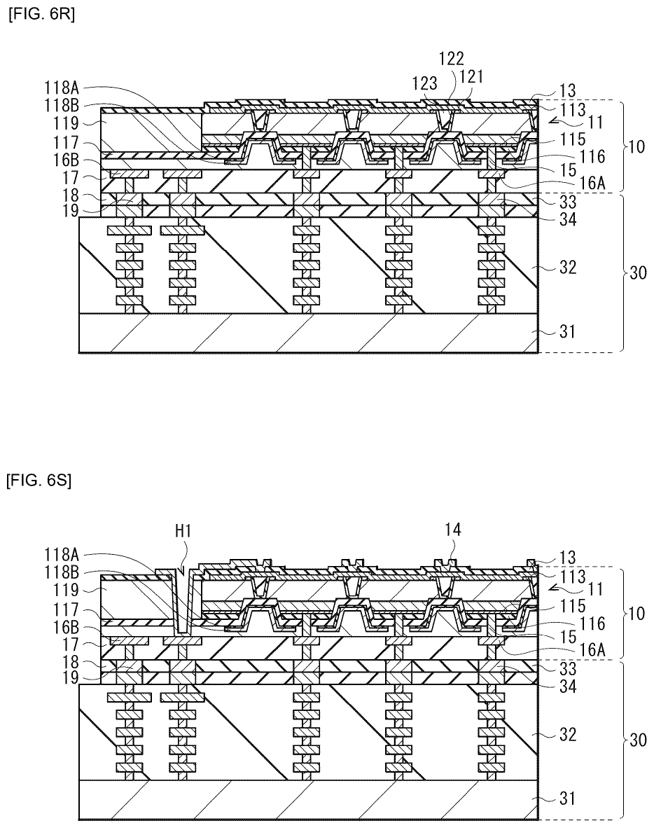

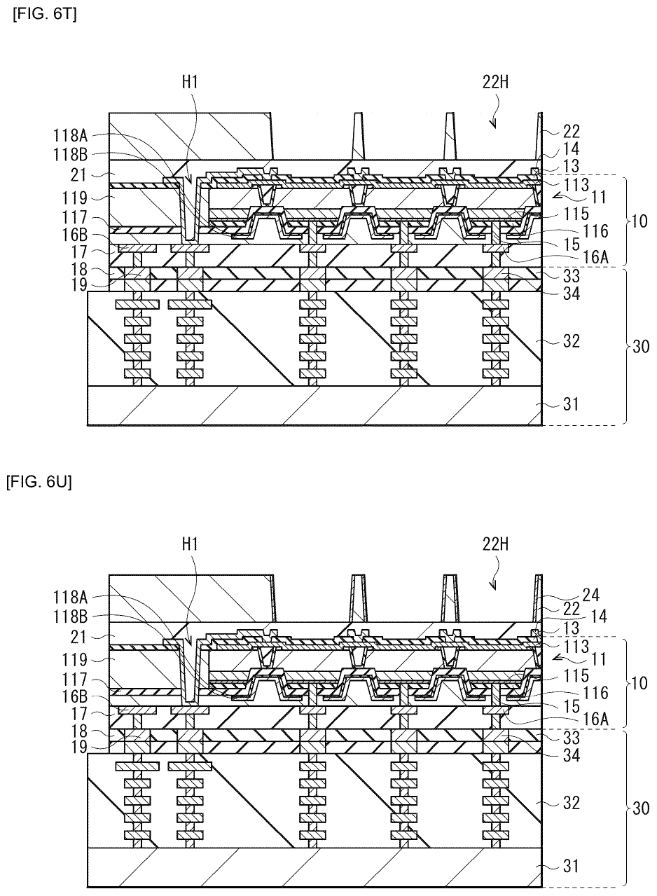

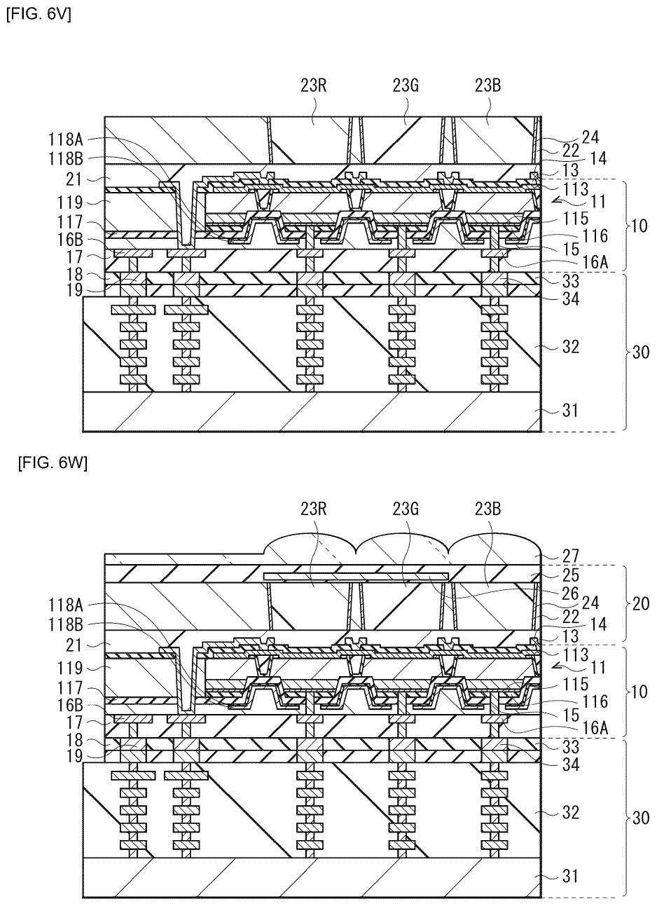

The light-emitting device 1 of the present embodiment may be manufactured, for example, as follows. FIGS. 5A to 5L and FIGS. 6A to 6W illustrate exemplary manufacturing steps of the light-emitting device 1.

First, as illustrated in FIG. 5A, using the sapphire substrate 114 as a growth substrate, the compound semiconductor layers 110 are formed by epitaxial crystal growth using, for example, a method such as a metal-organic chemical vapor deposition (MOCVD: Metal Organic Chemical Vapor Deposition) method or a molecular beam epitaxy (MBE: Molecular Beam Epitaxy) method. Subsequently, the electrode layer 115 and the insulating layer 116 are formed on the compound semiconductor layer 110 by, for example, a chemical vapor deposition (CVD) method. Next, the insulating layers 116 are planarized by, for example, chemical mechanical polishing (CMP).

Subsequently, as illustrated in FIG. 5B, the insulating layer 116, the electrode layer 115, and the compound semiconductor layer 110 are etched and patterned using, for example, a photolithography technique. Next, as illustrated in FIG. 5C, the sapphire substrate 114 is transferred so that the insulating layers 116 face the support substrate 51, and then the sapphire substrate 114 is cut and singulated. Subsequently, as illustrated in FIG. 5D, the individual sapphire substrates 114 are bonded to the transfer substrate 52 so that the insulating layers 116 face each other.

Next, as illustrated in FIG. 5E, the sapphire substrate 114 is thinned to, for example, a 500 nm thickness by grinding polishing. Subsequently, as illustrated in FIG. 5F, the inverted substrate 53 is bonded to the sapphire substrate 114 and reversed, and the transfer substrate 52 is peeled off. Next, the insulating layer 116 is planarized again by CMP, for example, and then the insulating layer 116 is bonded to the support substrate 54 as illustrated in 5G.

Subsequently, as illustrated in FIG. 5H, the sapphire substrate 114 is removed by, for example, laser lift-off. Next, as illustrated in FIG. 5I, the compound semiconductor layer 110 is thinned to a predetermined thickness (for example, until the second conductivity type layer 112 is exposed) by grinding polishing, for example. Subsequently, although not illustrated, a silicon nitride film, for example, is formed on the upper surface of the compound semiconductor layer 110 and the side surfaces of the compound semiconductor layer 110, the electrode layer 115, and the insulating layer 116, and then the buried layer 119 is formed on the support substrate 54 as illustrated in FIG. 5I.

Next, as illustrated in FIG. 5J, the buried layers 119 are planarized, and then the end portions of the support substrates 54 are trimmed. Subsequently, as illustrated in FIG. 5K, the buried layers 119 are bonded to the support substrate 55 by, for example, plasma-bonding, and then the support substrate 54 is peeled off as illustrated in FIG. 5L. Hereinafter, the inside of the frame X illustrated in FIG. 5L will be described in an enlarged manner.

First, as illustrated in FIG. 6A, the insulating layer 116 and the electrode layer 115 are etched and patterned using, for example, a photolithography technique. Subsequently, as illustrated in FIG. 6B, a portion of the compound semiconductor layer 110 is etched using, for example, a photolithography technique as the first separating part 12A to form a mesa structure including a portion of the first conductivity type layer 111 and a portion of the second conductivity type layer 112.

Next, as illustrated in FIG. 6C, for example, a SiN film is formed over the upper surface of the insulating layer 116 and the side and bottom surfaces of the first conductivity type layer 111 and the second conductivity type layer 112 constituting the insulating layer 116, the electrode layer 115, and the mesa structure by, for example, atomic layer deposition (ALD), thereby forming the protective layer 117. Subsequently, as illustrated in FIG. 6D, the reflective film 118A and the insulating film 118B are sequentially formed by, for 6D, a CVD method, and then an opening 118H is formed on the upper surface of the mesa. Next, as illustrated in FIG. 6E, the buried layers 119 are formed again by, for example, a CVD method to planarize the layers.

Subsequently, as illustrated in FIG. 6F, the insulating layers 17 in which the plugs 15, the plurality of pad portions 16A, and the pad electrodes 16B are buried are formed for each of the light-emitting elements 11. Next, as illustrated in FIG. 6G, the insulating layer 17 is thickened, and the insulating layer 18 is formed on the insulating layer 17. Subsequently, the end portions are trimmed as illustrated in FIG. 6H.

Next, as illustrated in FIG. 6I, after the opening 18H are formed on the pad portions 16A and the pad electrodes 16B, a plurality of pad portions 19 are formed by burying, for example, a Cu in the opening 18H as illustrated in FIG. 6J. Thereafter, as illustrated in 6K, the surfaces of the insulating layers 18 and the plurality of pad portions 19 are polished by, for example, CMP to planarize the junction surface with the driving substrate 30, and then the plurality of pad portions 34 and the plurality of pad portions 19 of the separately formed driving substrate 30 are bonded to each other by Cu—Cu bonding.

Subsequently, as illustrated in FIG. 6L, after the support substrate 55 is peeled off, the buried layer 119 is ground by, for example, CMP to expose the compound semiconductor layer 110, as illustrated in FIG. 6M. Next, as illustrated in FIG. 6N, a hard mask HM (insulating film 121) is patterned on the compound semiconductor layer 110 and the buried layer 119 using, for example, a photolithography technique. Subsequently, as illustrated in FIG. 6O, for example, a portion of the compound semiconductor layer 110 is etched to form the second separating part 12B. As a result, the compound semiconductor layers 110 are separated for each pixel (for example, the red pixel Pr, the green pixel Pg, and the blue pixel Pb).

Next, as illustrated in FIG. 6P, the reflective film 122 is formed on the side surface and the bottom surface of the compound semiconductor layer 110 by, for example, CVD. Subsequently, as illustrated in FIG. 6N, the insulating film 123 is formed by, for 6Q, a CVD method to fill the second separating part 12B, and then the insulating film 123 formed on the compound semiconductor layer 110 and the buried layer 119 is removed by, for example, CMP. Next, as illustrated in FIG. 6Q, the hard mask HM (insulating film 121) is etched using, for example, a photolithography technique to form an opening 121H.

Subsequently, as illustrated in FIG. 6R, an ITO film is formed by, for example, a CVD method, and then ITO film is patterned by, for example, a photolithography technique to form the electrode layers 113. Next, as illustrated in FIG. 6R, the insulating layers 13 are formed by, for example, CVD. Subsequently, as illustrated in FIG. 6S, an opening H1 reaching the opening and the pad electrode 16B is formed between the adjacent light-emitting elements 11 using, for example, a photolithography technique. After that, for example, a laminated film of Ti/W is formed by, for example, a CVD method, and then the laminated film is patterned by, for example, a photolithography technique to form the extraction electrodes 14 as illustrated in FIG. 6S.

Next, as illustrated in FIG. 6T, the planarization layer 21 and the partition wall layer 22 are formed in this order by, for example, a CVD method. Subsequently, as illustrated in FIG. 6T, an opening 22H is formed in the partition wall layers 22 above the respective light-emitting elements 11 using, for example, a photolithography technique. Subsequently, as illustrated in FIG. 6U, a Al film is formed on the upper surface of the partition wall layer 22, the side surface and the bottom surface of the opening 22H by, for example, a CVD method, and thereafter, Al film formed on the upper surface of the partition wall layer 22 and the bottom surface of the opening 22H is removed by etch-back to form the reflective film 24 on the side surface of the opening 22H.

Next, as illustrated in FIG. 6V, wavelength conversion layers 23 (23R, 23G, and 23B) of respective colors are formed in the opening 22H by a coating method such as an ink-jet method. Thereafter, as illustrated in FIG. 6W, after the protective layer 25 including the wavelength selective layer 26 is formed on the partition wall layer 22 and the wavelength conversion layer 23, the on-chip lens layer 27 is bonded. Thus, the light-emitting device 1 illustrated in FIG. 1 is completed.

### (1-3. Workings and Effects)

In the light-emitting device 1 of the present embodiment, the separating part 12 is provided which separates the compound semiconductor layer 110 including the light-emitting region and having the front surface (surface 11S2) facing the driving substrate 30 and the back surface (surface 11S1) serving as the light-emitting surface. The separating part 12 includes the first separating part 12A that separates the compound semiconductor layer 110 from the surface 11S2 side toward the surface 11S1 side, and the second separating part 12B that separates the compound semiconductor layer 110 from the surface 11S1 side toward the surface 11S2 side, and has a bottom portion in contact with the bottom portion of the first separating part 12A. The second separating part 12B has an inverted tapered shape in which an angle formed between the separation surface 12BS and the surface 11S2 of the compound semiconductor layer 110 is an obtuse angle. This reduces light leakage into neighboring pixels (e.g., red pixel Pr, green pixel Pg, and blue pixel Pb). This will be described below.

For example, in a light-emitting device including a micro LED as a light source (light-emitting device), light leakage (crosstalk) between adjacent pixels and color mixing associated therewith are problems. In a general light-emitting device, a means for reducing light leakage is used by forming a reflective film on a sidewall after element separation or a sidewall of a wavelength conversion layer.

However, in a general method of manufacturing a light-emitting device, since the opening of the element separating part has, for example, a forward tapered shape or a vertical shape with respect to the driving substrate surface, leakage light passing through the upper portion of the side wall of the element isolation is likely to occur, and there still remains a risk of color mixing due to penetration of the leakage light into the adjacent wavelength conversion layer.

In contrast, in the present embodiment, the compound semiconductor layer 110 including the light-emitting regions and having the front surface (surface 11S2) facing the driving substrate 30 and the back surface (surface 11S1) serving as the light-emitting surface, the separating part 12 (second separating part 12B) separating from the surface 11S1 toward the surface 11S2 side, the angle formed between the separation surface 12BS and the surface 11S1 has an inverted taper that is obtuse. As a result, light leakage to neighboring pixels (for example, the red pixel Pr, the green pixel Pg, and the blue pixel Pb) is reduced as compared with the element separating part having the forward tapered shape or the vertical shape.

As described above, it is possible to reduce color mixing in the light-emitting device 1 of the present embodiment and the image display device 100 including the same.

In addition, there is a step of separating GaN chip into, for example, pixels in the manufacturing step in a light-emitting device having a micro LED using gallium nitride (GaN) as a light source. At this time, GaN tip floats because of the internal stresses, and GaN tip is peeled off from the substrate in a subsequent process. Since cracks or the like are generated in the peeled GaN tip, it is difficult to fabricate LED device.

In contrast, in the present embodiment, the first separating part 12A that separates the compound semiconductor layer 110 from the surface 11S2 side toward the surface 11S1 to the middle, and the second separating part 12B that separates the compound semiconductor layer 110 from the surface 11S1 side toward the surface 11S2 side and whose bottom portion is in contact with the bottom portion of the first separating part 12A are formed. Specifically, in the manufacturing process, the first separating part 12A that separates from the surface 11S2 side of the compound semiconductor layer 110 toward the surface 11S1 side (a portion of the first conductivity type layer 111 and the second conductivity type layer 112) is formed to leave a portion of the compound semiconductor layer 110, and after the protective layer 117 is formed as a sidewall on the side surface of the first separating part 12A, the second separating part 12B that separates from the surface 11S1 side of the compound semiconductor layer 110 is formed to separate the compound semiconductor layer 110 for each pixel (for example, the red pixel Pr, the green pixel Pg, and the blue pixel Pb). This suppresses peeling of GaN chip when the compressive stresses on GaN tip are released.

Therefore, it is possible to improve the manufacturing yield of the light-emitting device 1 of the present embodiment and the image display device 100 including the same.

Next, Modifications 1 and 2 and application examples of the present disclosure will be described. Components corresponding to the light-emitting device 1 of the above-described embodiment are denoted by the same reference numerals, and description thereof will be omitted.

### 2. Modification Examples

### (2-1. Modification 1)

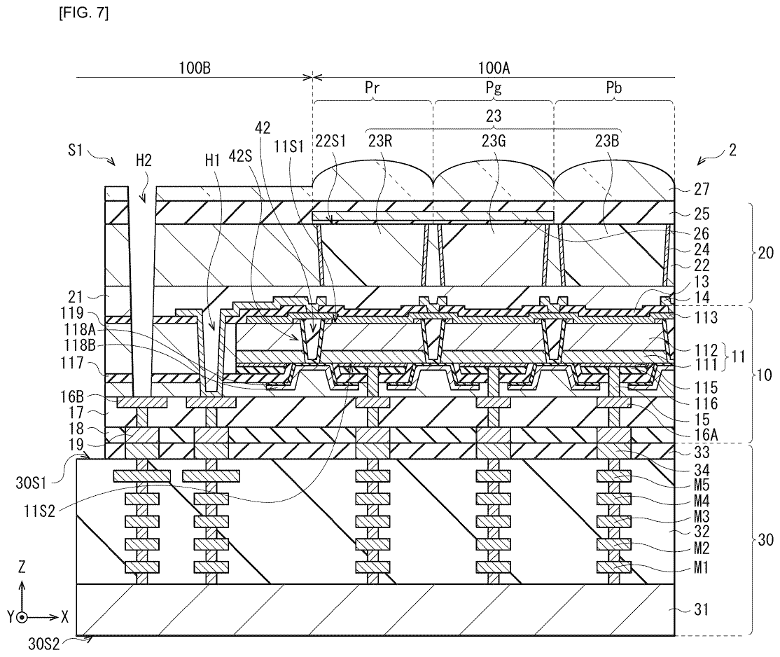

FIG. 7 schematically illustrates an example of a cross-sectional configuration of a light-emitting device (light-emitting device 2) according to Modification 1 of the present disclosure. The light-emitting device 2 may be suitably applied to an image display device (for example, the image display device 100, see FIG. 10) called a so-called LED display, similarly to the light-emitting device 1 of the above-described embodiment.

In the above-described embodiment, the compound semiconductor layer 110 is separated from the surface 11S2 toward the surface 11S1, and the compound semiconductor layer 110 is separated from the surface 11S1 toward the surface 11S2, so that the separating part 12 including the second separating part 12B whose bottom portion is in contact with the bottom portion of the first separating part 12A is formed. On the other hand, in the light-emitting device 2 of the present modification, the separating part 12 is replaced with a separating part 42 that collectively separates the compound semiconductor layers 110 from the surface 11S1 toward the surface 11S2. The separating part 42 corresponds to a specific example of a “separating part” in an embodiment of the present disclosure.

As described above, the separating part 42 separates the compound semiconductor layers 110 and forms the light emitting elements 11 for each pixel (for example, the red pixel Pr, the green pixel Pg, and the blue pixel Pb). The separating part 42 separates the compound semiconductor layer 110 from the surface 11S1 side toward the surface 11S2 side, and has an inverted tapered shape in which an angle formed between the separation surface 42S and the surface 11S2 of the compound semiconductor layer 110 is obtuse. As a result, color mixing caused by incidence of light (outgoing light L) emitted from the light emitting region in, for example, an oblique direction onto the wavelength conversion layer 23 (for example, the red wavelength conversion layer 23R, the green wavelength conversion layer 23G, and the blue wavelength conversion layer 23B) provided in the adjacently disposed pixels (for example, the red pixel Pr, the green pixel Pg, and the blue pixel Pb) is reduced. The effect of reducing color mixing due to the reverse tapered shape of the separating part 42 has a trade-off relationship with the light extraction efficiency. Therefore, the angle formed between the separation surface 42S and the surface 11S2 of the compound semiconductor layer 110 is preferably greater than 90°, for example, 100° or less. As a result, it is possible to maintain high light extraction efficiency while reducing color mixture.

The separating part 42 is a groove penetrating from the surface 11S1 between the surface 11S1 and the surface 11S2 of the compound semiconductor layers 110. Similarly to the second separating part 12B of the above-described embodiment, the reflective film 122 is provided in the groove over the separation surface 42S and the bottom surface. As a result, the light emitted from the light emitting region in an oblique direction, for example, is reflected by the reflective film 122, and the light is suppressed from entering the wavelength conversion layer 23 (for example, the red wavelength conversion layer 23R, the green wavelength conversion layer 23G, and the blue wavelength conversion layer 23B) provided in the adjacent pixels (for example, the red pixel Pr, the green pixel Pg, and the blue pixel Pb). The groove is further filled with an insulating film 123. The material filled in the groove may be filled with a resin material in addition to the insulating material. Accordingly, it is possible to reduce the effect of the thermal expansion coefficient difference between the compound semiconductor layers 110 and the support substrate 31 made of, for example, Si.

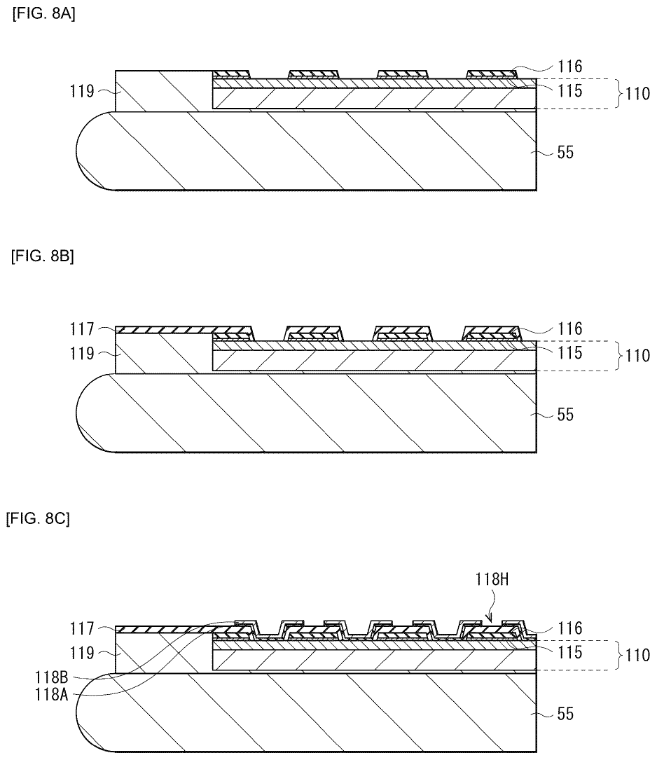

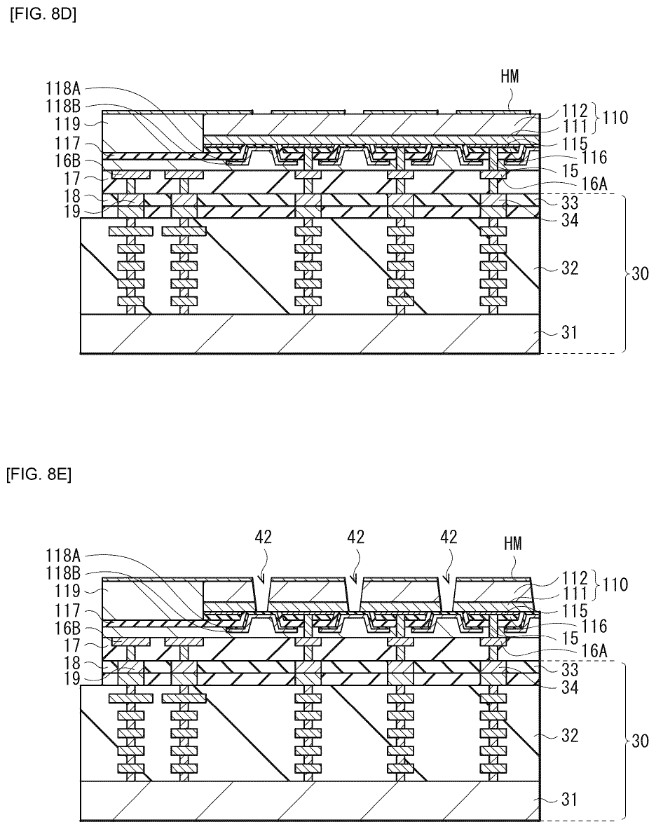

The light-emitting device 2 may be manufactured, for example, as follows. FIGS. 8A to 8E illustrate exemplary manufacturing steps of the light-emitting device 2.

The compound semiconductor layers 110 are separated into a plurality of chips through the same processes as those in the above-described embodiment (5A to 5L).

Next, as illustrated in FIG. 8A, the insulating layer 116 and the electrode layer 115 are etched and patterned using, for example, a photolithography technique in the same manner as in the above-described embodiment. Subsequently, as illustrated in FIG. 8B, for example, a SiN film is formed over the upper surface of the insulating layer 116 and the side surface and the bottom surface of the insulating layer 116 by, for example, an ALD method, and then SiN film is etched by, for example, a photolithography technique to form the protective layer 117 as a sidewall. Next, as illustrated in FIG. 8C, as illustrated in FIG. 6D, the reflective film 118A and the insulating film 118B are sequentially formed by, for example, a CVD method, and then an opening 118H is formed on the upper surface of the mesa structure.

After that, through the same processes as in the above-described embodiment (6E to 6M), as illustrated in FIG. 8D, a hard mask HM (insulating film 121) is patterned on the compound semiconductor layer 110 and the buried layer 119 using, for example, a photolithography technique.

Subsequently, as illustrated in FIG. 8E, for example, the compound semiconductor layers 110 are etched to form the separating parts 42. As a result, the compound semiconductor layers 110 are separated for each pixel (for example, the red pixel Pr, the green pixel Pg, and the blue pixel Pb). Thereafter, the light-emitting device 2 illustrated in FIG. 7 is completed by passing through the same processes as those in the above-described embodiment (FIGS. 6P to 6W).

In the light-emitting device 2 of the present modification, the compound semiconductor layer 110 is collectively separated from the surface 11S1 toward the surface 11S2, and the separating part 42 having an inverted tapered shape in which an angle formed between the separation surface 42S and the surface 11S1 is an obtuse angle is provided. As a result, light leakage to neighboring pixels (for example, the red pixel Pr, the green pixel Pg, and the blue pixel Pb) is reduced as in the above-described embodiment.

As described above, it is possible to reduce color mixing in the light-emitting device 2 of the present modification example and the image display device 100 including the same.

### (2-2. Modification 2)

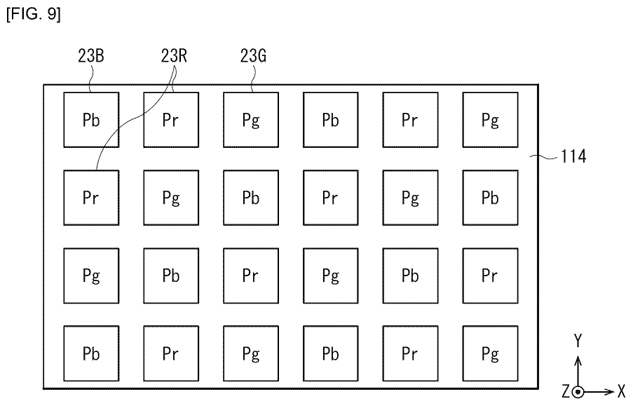

In the above-described embodiment, the partition wall layer 22 has substantially regular hexagonal opening 22H for each color pixel Pr, Pg, and Pb, but the planar shape of the opening 22H is not limited thereto. For example, as illustrated in FIG. 9, a rectangular opening 22H may be provided. In this case, the plurality of light-emitting elements 11 and the opening 22H may be two-dimensionally arranged in a matrix, for example. The wavelength conversion layers 23 (the red wavelength conversion layer 23A, the green wavelength conversion layer 23G, and the blue wavelength conversion layer 23B) provided in the respective opening 22H are arranged in a Bayer shape, for example.

### 3. Application Examples

### Application Example 1

FIG. 10 is a perspective diagram illustrating an example of a schematic configuration of an image display device (image display device 100). The image display device 100 is called a so-called LED display, and a light-emitting device (for example, the light-emitting device 1) of the present disclosure is used as a display pixel. As illustrated in FIG. 10, for example, the image display device 100 includes a display panel 120 and a control circuit 140 that drives the display panel 120.

The display panel 120 is a display panel in which a mounting substrate 120A and a counter substrate 120B are superimposed on each other. A front surface of the counter substrate 120B serves as a video display portion surface, and a display region (display portion 100A) is provided at a central portion thereof, and a frame portion 100B which is a non-display region is provided around the display region.

FIG. 11 is a diagram illustrating an example of a wiring layout of an area corresponding to the display portion 100A on the surface of the mounting substrate 120A on the counter substrate 120B. As illustrated in FIG. 11, for example, a plurality of data wirings 124 are formed to extend in a predetermined direction and arranged in parallel at a predetermined pitch in a region corresponding to the display portion 100A on the front surface of the mounting substrate 120A. Further, for example, a plurality of scan wirings 125 are formed to extend in a direction intersecting (for example, orthogonal to) the data wirings 124 in a region corresponding to the display portion 100A on the surface of the mounting substrate 120A, and are arranged in parallel at a predetermined pitch. The data wiring 124 and the scan wiring 125 are made of, for example, a conductive material such as Cu.

The scan wiring 125 is formed on, for example, the outermost layer, and is formed on, for example, an insulating layer (not illustrated) formed on the surface of the base material. The base material of the mounting substrate 120A is made of, for example, a silicon substrate, a resin substrate, or the like, and the insulating layer on the base material is made of, for example, SiN, SiO, aluminum oxide (AlO), or a resin material. On the other hand, the data wiring 124 is formed in a layer (for example, a layer lower than the outermost layer) different from the outermost layer including the scan wiring 125, and is formed in, for example, an insulating layer on the base material.

Near the intersection of the data wiring 124 and the scan wiring 125 is a display pixel 126, and a plurality of display pixels 126 are arranged in a matrix in the display portion 100A. For example, each color pixel Pr, Pg, and Pb of the light-emitting device 1 is mounted on each of the display pixels 126.

In the light-emitting device 1, for example, a pair of other electrodes are provided for each color pixel Pr, Pg, and Pb, or one of the pair of terminal electrodes is provided for each color pixel Pr, Pg, and Pb and the other is provided for each color pixel. One terminal electrode is electrically coupled to the data wiring 124, and the other terminal electrode is electrically coupled to the scan wiring 125. For example, one terminal electrode is electrically coupled to the pad electrode 124B at the distal end of the branch 124A provided in the data wiring 124. Further, for example, the other terminal electrode is electrically coupled to the pad electrode 125B at the distal end of the branch 125A provided in the scan wiring 125.

Each pad electrode 124B and 125B is formed, for example, in the outermost layer, and is provided, for example, in a portion where each light-emitting device 1 is mounted, as illustrated in FIG. 11. Here, the pad electrode 124B or 125B is made of a conductive material such as Au (gold).

The mounting substrate 120A is further provided with, for example, a plurality of struts (not illustrated) for regulating the interval between the mounting substrate 120A and the counter substrate 120B. The support column may be provided in an area facing the display portion 100A or may be provided in an area facing the frame portion 100B.

The counter substrate 120B includes, for example, a glass substrate, a resin substrate, or the like. In the counter substrate 120B, the light-emitting device 1 may have a flat surface, but preferably has a rough surface. The rough surface may be provided over the entire area facing the display portion 100A, or may be provided only in the area facing the display pixel 126. The rough surface has fine irregularities in which light emitted from the color pixel Pr, Pg, and Pb enters the rough surface. The unevenness of the rough surface may be produced by, for example, sand blasting, dry etching, or the like.

The control circuit 140 drives each display pixel 126 (each light-emitting device 1) based on a picture signal. The control circuit 140 includes, for example, a data driver that drives the data wiring 124 coupled to the display pixel 126 and a scan driver that drives the scan wiring 125 coupled to the display pixel 126. For example, as illustrated in FIG. 10, the control circuit 140 may be provided separately from the display panel 120 and coupled to the mounting substrate 120A via a wiring, or may be mounted on the mounting substrate 120A.

### Application Example 2

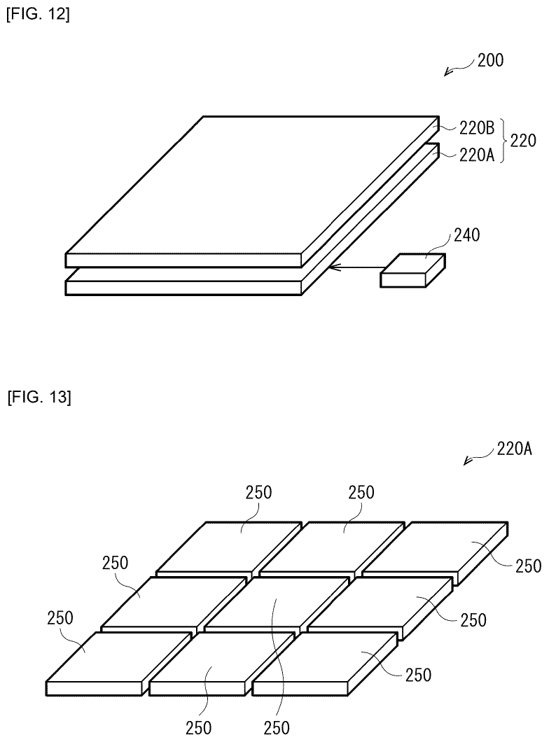

FIG. 12 is a perspective diagram illustrating another configuration example (image display device 200) of the image display device using the light-emitting device (for example, light-emitting device 1) of the present disclosure. The image display device 200 is called a so-called tiling display using a plurality of light-emitting devices using LED as a light source. For example, as illustrated in FIG. 12, the image display device 200 includes a display panel 220 and a control circuit 240 that drives the display panel 220.

The display panel 220 is a display panel in which a mounting substrate 220A and a counter substrate 220B are superimposed on each other. The face of the counter substrate 220B serves as an image display portion surface, and has a display portion at a central portion thereof, and a frame portion which is a non-display area is provided around the display portion (neither of which is illustrated). The counter substrate 220B is disposed, for example, at a position facing the mounting substrate 220A with a predetermined gap therebetween. The counter substrate 220B may be in contact with the upper surface of the mounting substrate 220A.

FIG. 13 schematically illustrates an exemplary configuration of a mounting substrate 220A. For example, as illustrated in FIG. 13, the mounting substrate 220A includes a plurality of unit substrates 250 laid in tiles. In FIG. 13, the mounting substrate 220A is configured by the nine unit substrates 250, but the number of the unit substrates 250 may be 10 or more or 8 or less.

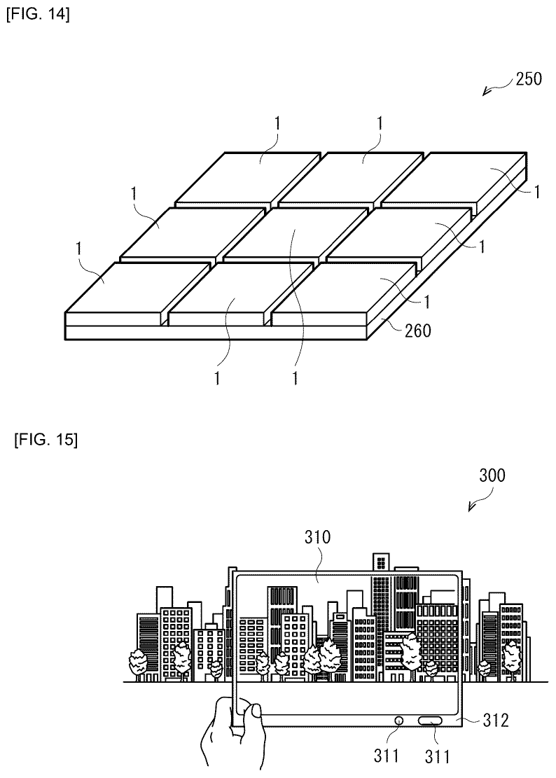

FIG. 14 illustrates an example of a configuration of the unit substrate 250. The unit substrate 250 includes, for example, the plurality of light-emitting devices 1 laid in tiles, and a support substrate 260 that supports the light-emitting devices 1. The unit substrate 250 further includes a control substrate (not illustrated). The support substrate 260 is made of, for example, a metallic frame (metal plate), a wiring substrate, or the like.

When the support substrate 260 is composed of wiring substrate, it can also serve as a control substrate. At this time, at least one of the support substrate 260 and the control substrate is electrically coupled to each of the light-emitting devices 1.

### Application Example 3

FIG. 15 illustrates the appearance of a transparent display 300.

The transparent display 300 includes, for example, a display portion 310, an operation unit 311, and a housing 312. A light-emitting device of the present disclosure (for example, the light-emitting device 1) is used for the display portion 310. The transparent display 300 may display an image and character information while passing through the background of the display portion 310.

In the transparent display 300, a light-transmitting substrate is used as the mounting substrate. Each electrode provided in the light-emitting device 1 is formed using a light-transmitting conductive material as in the case of the mounting substrate. Alternatively, each electrode has a structure that is difficult to be visually recognized by supplementing the wiring width or reducing the thickness of the wiring. Further, the transparent display 300 can perform black display by superimposing, for example, a liquid crystal layer including a driving circuit, and may perform switching between transmittance and black display by controlling the light distribution direction of the liquid crystal.

Although the present technology has been described with reference to the embodiment and the modification examples 1 and 2 and the application example, the present technology is not limited to the above-described embodiment and the like, and various modifications are possible. For example, in the above-described embodiments and the like, an example in which the light emitted from the light emitting element 11 is blue light or ultraviolet light has been described, but it is not limited thereto. For example, in the light-emitting device 1, a light-emitting element in which two or more kinds of light such as blue light and green light, ultraviolet light and green light are emitted may also be used.

Further, in the above-described embodiments and the like, the respective members constituting the light-emitting device 1 and the like have been specifically described, but it is not necessary to include all the members, and other members may be further provided.

It is to be noted that the effects described in the present specification are mere examples and description thereof is non-limiting. Other effects may be also provided.

The present technology may have the following configurations. According to the present technology of the following configurations, the separating part that separates the light-emitting part made of the compound semiconductor for each pixel has an inverted tapered shape that is inclined toward the light-emitting part in which the separation surface thereof is separated from the first surface that faces the driving substrate of the light-emitting part toward the second surface serving as the light-emitting surface side. This makes it possible to reduce leakage of light into adjacent pixels and reduce color mixing.

(1)

A light-emitting device including:
a driving substrate;
a compound semiconductor layer including a light-emitting region and having and a first surface facing the driving substrate and a second surface serving as a light-emitting surface on a side opposite to the first surface; and
a separating part that separates at least a portion of the compound semiconductor layer from the second surface toward the first surface for each pixel, and has an inverted tapered shape in which an angle formed between a separation surface thereof and the first surface is an obtuse angle.
   (2)

The light-emitting device according to (1), in which
the separating part includes a first separating part that separates the compound semiconductor layer from the first surface side, and a second separating part that separates the compound semiconductor layer from the second surface side and contacts the first separating part, and
a separation surface of the second separating part separating the compound semiconductor layer has the inverted tapered shape.
   (3)

The light-emitting device according to (2), in which a separation surface of the first separating part separating the compound semiconductor layer has a forward tapered shape in which an angle formed between the separation surface and the first surface is an acute angle.

(4)

The light-emitting device according to (2) or (3), in which a width of a bottom surface of the first separating part is larger than a width of a bottom surface of the second separating part.

(5)

The light-emitting device according to any one of (2) to (4), in which a separation surface of the first separating part separating the compound semiconductor layer is protected by a side wall formed by extending the compound semiconductor layer from the first surface side to the separation surface.

(6)

The light-emitting device according to (5), in which the side wall includes a laminated film including an insulating film and a reflective film formed in this order from the compound semiconductor layer side.

(7)

The light-emitting device according to any one of (2) to (6), in which an insulating material is embedded in the second separating part.

(8)

The light-emitting device according to any one of (2) to (7), in which a resin material is embedded in the second separating part.

(9)

The light-emitting device according to any one of (1) to (8), in which a taper angle of the separation surface is greater than 90° and less than or equal to 100°.

(10)

The light-emitting device according to any one of (1) to (9), further including
a pixel array section including a plurality of pixels arranged in an array, in which
each of the plurality of pixels includes a light-emitting part formed by separating the compound semiconductor layer for each of the pixels by the separating part, and
a wavelength conversion layer that converts a wavelength of light emitted from the light-emitting part on the light-emitting surface side of the light-emitting part.
   (11)

The light-emitting device according to (10), in which
the plurality of pixels includes a first pixel, a second pixel, and a third pixel,
the first pixel includes, as the wavelength conversion layer, a first wavelength conversion layer that converts the light emitted from the light-emitting part into red light,
the second pixel includes, as the wavelength conversion layer, a second wavelength conversion layer that converts the light emitted from the light-emitting part into green light, and
the third pixel includes, as the wavelength conversion layer, a third wavelength conversion layer that transmits the light emitted from the light-emitting part therethrough or converts the light emitted from the light-emitting part into blue light.
   (12)

An image display device including
a light-emitting device, the light-emitting device including:
a driving substrate;
a compound semiconductor layer including a light-emitting region and having and a first surface facing the driving substrate and a second surface serving as a light-emitting surface on a side opposite to the first surface; and
a separating part that separates at least a portion of the compound semiconductor layer from the second surface toward the first surface for each pixel, and has an inverted tapered shape in which an angle formed between a separation surface thereof and the first surface is an obtuse angle.

The present application claims the benefit of Japanese Priority Patent Application JP2022-193717 filed with the Japan Patent Office on Dec. 2, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A light-emitting device comprising:
a driving substrate;
a compound semiconductor layer including a light-emitting region and having and a first surface facing the driving substrate and a second surface serving as a light-emitting surface on a side opposite to the first surface; and
a separating part that separates at least a portion of the compound semiconductor layer from the second surface toward the first surface for each pixel, and has an inverted tapered shape in which an angle formed between a separation surface thereof and the first surface is an obtuse angle.

2. The light-emitting device according to claim 1, wherein
the separating part includes a first separating part that separates the compound semiconductor layer from the first surface side, and a second separating part that separates the compound semiconductor layer from the second surface side and contacts the first separating part, and
a separation surface of the second separating part separating the compound semiconductor layer has the inverted tapered shape.

3. The light-emitting device according to claim 2, wherein a separation surface of the first separating part separating the compound semiconductor layer has a forward tapered shape in which an angle formed between the separation surface and the first surface is an acute angle.

4. The light-emitting device according to claim 2, wherein a width of a bottom surface of the first separating part is larger than a width of a bottom surface of the second separating part.

5. The light-emitting device according to claim 2, wherein a separation surface of the first separating part separating the compound semiconductor layer is protected by a side wall formed by extending the compound semiconductor layer from the first surface side to the separation surface.

6. The light-emitting device according to claim 5, wherein the side wall includes a laminated film including an insulating film and a reflective film formed in this order from the compound semiconductor layer side.

7. The light-emitting device according to claim 2, wherein an insulating material is embedded in the second separating part.

8. The light-emitting device according to claim 2, wherein a resin material is embedded in the second separating part.

9. The light-emitting device according to claim 1, wherein a taper angle of the separation surface is greater than 90° and less than or equal to 100°.

10. The light-emitting device according to claim 1, further comprising
a pixel array section including a plurality of pixels arranged in an array, wherein
each of the plurality of pixels includes a light-emitting part formed by separating the compound semiconductor layer for each of the pixels by the separating part, and
a wavelength conversion layer that converts a wavelength of light emitted from the light-emitting part on the light-emitting surface side of the light-emitting part.

11. The light-emitting device according to claim 10, wherein
the plurality of pixels includes a first pixel, a second pixel, and a third pixel,
the first pixel includes, as the wavelength conversion layer, a first wavelength conversion layer that converts the light emitted from the light-emitting part into red light,
the second pixel includes, as the wavelength conversion layer, a second wavelength conversion layer that converts the light emitted from the light-emitting part into green light, and
the third pixel includes, as the wavelength conversion layer, a third wavelength conversion layer that transmits the light emitted from the light-emitting part therethrough or converts the light emitted from the light-emitting part into blue light.

12. An image display device comprising
a light-emitting device, the light-emitting device comprising:
a driving substrate;
a compound semiconductor layer including a light-emitting region and having and a first surface facing the driving substrate and a second surface serving as a light-emitting surface on a side opposite to the first surface; and
a separating part that separates at least a portion of the compound semiconductor layer from the second surface toward the first surface for each pixel, and has an inverted tapered shape in which an angle formed between a separation surface thereof and the first surface is an obtuse angle.
